(19) United States
(12) Patent Application Publication
(10) Pub. No.: US 2008/0001247 A1
(43) Pub. Date: Jan. 3, 2008

(54) Mesa Optical Sensors and Methods of Manufacturing the Same

(76) Inventors: Wagdi W. Abadeer, Jericho, VT (US); Jack A. Mandelman, Flat Rock, NC (US)

Correspondence Address: IBM CORPORATION, INTELLECTUAL PROPERTY LAW, DEPT 917, 3605 HIGHWAY 52 NORTH, ROCHESTER, MN, 55901-7829, US

(21) Appl. No.: 11/427,951

(22) Filed: Jun. 30, 2006

(51) Int. Cl. H01L 31/06

(52) U.S. Cl. 257/462

(57) ABSTRACT

In a first aspect, a first method of determining radiation intensity is provided. The first method includes the steps of (1) providing a semiconductor device having (a) a silicon mesa; and (b) photo-gate conductor material along at least three sidewalls of the silicon mesa; (2) forming a depletion region in the silicon mesa; and (3) in response to radiation impacting the semiconductor device, creating a signal in the semiconductor device, wherein the signal has a level related to an intensity of the radiation. Numerous other aspects are provided.

### FIELD OF THE INVENTION

The present invention relates generally to semiconductor device manufacturing, and more particularly to mesa optical sensors and methods of manufacturing the same.

### BACKGROUND

Conventional photodiodes and photogates may be employed to detect electromagnetic radiation. A conventional photodiode may include a reverse-biased PN-junction that includes a depletion region. In response to radiation, electron/hole pairs may be formed in the depletion region. An electric field across the depletion region causes the electrons and holes of such pairs to drift apart, which creates a detectable change in voltage across the photodiode (such as when the photodiode is left floating after being precharged).

However, some conventional photodiodes may include an undepleted region through which radiation passes before reaching the depletion region. Radiation may be absorbed by the undepleted region and electron/hole pairs may diffuse apart therein at a rate slower than the drift rate in the depletion region, which slows a response of the photodiode to the radiation.

Further, the depletion region of some conventional photodiodes employing planar technology may be shallow, and therefore, may not be able to detect all types of radiation (e.g., radiation which must deeply penetrate a depletion region before being detected). To compensate for a shallow depletion region, some conventional photodiodes increase a surface area of the depletion region. However, such a solution inefficiently consumes chip area. Alternatively, depletion regions of some conventional photodiodes are formed in trenches. However, in response to radiation, electron/hole pairs may only be created in a small portion of depletion region volume, which adversely affects detection.

Crystal defects in a PN-junction of a photodiode may cause thermal noise generation, which also adversely affects radiation detection. A conventional photogate may employ planar technology to provide a depletion region with a large area and a small PN-junction. The small-PN junction may reduce the above-described noise problem. However, the depletion region of such a photogate may be shallow, and therefore, may suffer from problems associated therewith. Due to the disadvantages of conventional photodiodes and photodetectors, improved optical sensors and methods of manufacturing the same are desired.

### SUMMARY OF THE INVENTION

In a first aspect of the invention, a first method of determining radiation intensity is provided. The first method includes the steps of (1) providing a semiconductor device having (a) a silicon mesa; and (b) photo-gate conductor material along at least three sidewalls of the silicon mesa; (2) forming a depletion region in the silicon mesa; and (3) in response to radiation impacting the semiconductor device, creating a signal in the semiconductor device, that has a level related to an intensity of the radiation.

In a second aspect of the invention, a first apparatus for determining radiation intensity is provided. The first apparatus includes a semiconductor device having (1) a silicon mesa; and (2) photo-gate conductor material along at least three sidewalls of the silicon mesa. The semiconductor device is adapted to (a) form a depletion region in the silicon mesa; and (b) create a signal in the semiconductor device in response to radiation impacting the semiconductor device, wherein the signal has a level related to an intensity of the radiation.

In a third aspect of the invention, a first system for determining radiation intensity is provided. The first system includes (1) a substrate; and (2) at least one semiconductor device formed on the substrate. The semiconductor device has (a) a silicon mesa; and (b) photo-gate conductor material along at least three sidewalls of the silicon mesa. The semiconductor device is adapted to (i) form a depletion region in the silicon mesa; and (ii) create a signal in the semiconductor device in response to radiation impacting the semiconductor device, wherein the signal has a level related to an intensity of the radiation. Numerous other aspects are provided, as are systems and apparatus in accordance with these and other aspects of the invention.

Other features and aspects of the present invention will become more fully apparent from the following detailed description, the appended claims and the accompanying drawings.

### BRIEF DESCRIPTION OF THE FIGURES

FIG. 1 illustrates a vertical cross-sectional view of an apparatus for determining radiation intensity in accordance with an embodiment of the present invention.

FIG. 2 illustrates a horizontal cross-sectional view of a simulated version of a first exemplary apparatus in accordance with an embodiment of the present invention.

FIG. 3 illustrates a horizontal cross-sectional view of a simulated version of a second exemplary apparatus in accordance with an embodiment of the present invention.

FIG. 4 is a top view of a first exemplary system for determining radiation intensity in accordance with an embodiment of the present invention.

FIG. 5 is a schematic circuit representation of the system of FIG. 4 in accordance with an embodiment of the present invention.

FIG. 6 is a top view of a second exemplary system for determining radiation intensity in accordance with an embodiment of the present invention.

FIG. 7 illustrates a cross-sectional side view of a substrate following a first step of a method of manufacturing an apparatus for determining radiation intensity in accordance with an embodiment of the present invention.

FIG. 8 illustrates a cross-sectional side view of the substrate following a second step of the method of manufacturing an apparatus for determining radiation intensity in accordance with an embodiment of the present invention.

FIGS. 9A-B illustrate respective top and cross-sectional side views of the substrate following a third step of the method of manufacturing an apparatus for determining radiation intensity in accordance with an embodiment of the present invention.

FIGS. 10A-B illustrate respective top and cross-sectional side views of the substrate following a fourth step of the method of manufacturing an apparatus for determining radiation intensity in accordance with an embodiment of the present invention.

FIGS. 11A-C illustrate respective top, cross-sectional side and cross-sectional front views of the substrate following a fifth step of the method of manufacturing an apparatus for determining radiation intensity in accordance with an embodiment of the present invention.

FIGS. 12A-C illustrate respective top, cross-sectional side and cross-sectional front views of the substrate following a sixth step of the method of manufacturing an apparatus for determining radiation intensity in accordance with an embodiment of the present invention.

FIGS. 13A-C illustrate respective top, cross-sectional side and cross-sectional front views of the substrate following a seventh step of the method of manufacturing an apparatus for determining radiation intensity in accordance with an embodiment of the present invention.

FIGS. 14A-C illustrate respective top, cross-sectional side and cross-sectional front views of the substrate following an eighth step of the method of manufacturing an apparatus for determining radiation intensity in accordance with an embodiment of the present invention.

FIGS. 15A-D illustrate first cross-sectional side, second cross-sectional side, first cross-sectional front and second cross-sectional front views of the substrate following a ninth step of the method of manufacturing an apparatus for determining radiation intensity in accordance with an embodiment of the present invention.

### DETAILED DESCRIPTION

The present invention provides improved optical sensors and methods of manufacturing the same. More specifically, the present invention provides a photogate including a transistor with a semiconductor mesa (e.g., fin). The mesa may include gate conductor (e.g., photo-gate conductor) material along three side walls of the mesa. When a voltage is applied to the gate conductor, a large volume of the semiconductor mesa may become depleted such that a deep depletion region having a large volume is formed. A top surface of the mesa may be exposed to radiation. When the mesa is exposed to radiation, the depth and large volume of the mesa may enable a large number of electron/hole pairs to form and drift apart therein. Consequently, the radiation may create a signal (e.g., a voltage signal) in mesa having a level (e.g., voltage) related to the intensity of the radiation. The optical sensor may include a transfer gate and/or a collection diffusion region adapted to receive the signal. The collection diffusion region may be coupled to known circuitry adapted to determine the radiation intensity having a level related to the signal. The depth of the mesa may enable the improved optical sensor to avoid problems associated with conventional photodiodes and photogates. For example, the mesa of the photogate may provide a depletion region with an increased effective depth which may improve a photo-efficiency of the photogate.

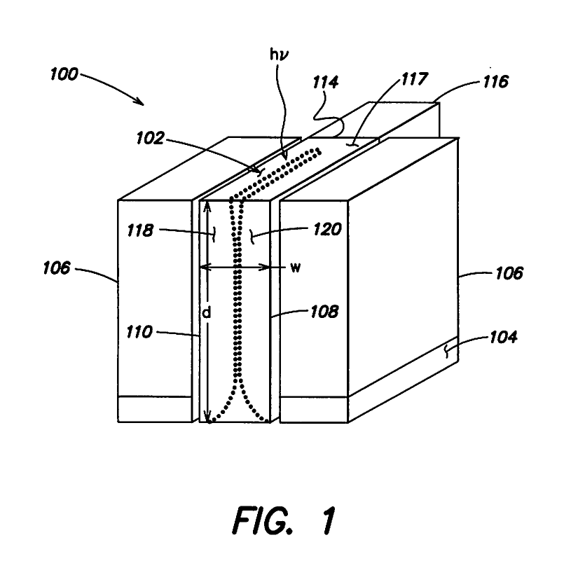

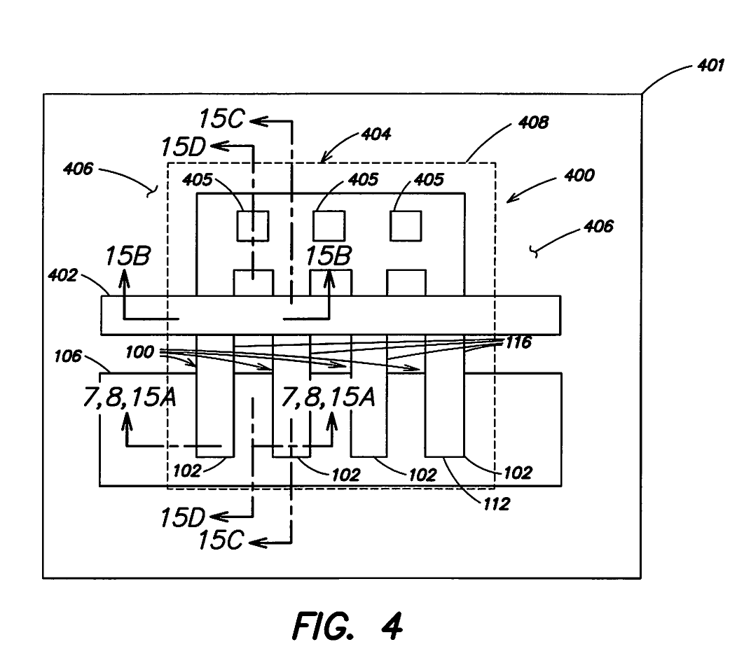

FIG. 1 illustrates a vertical cross-sectional view of an apparatus 100 for determining radiation intensity in accordance with an embodiment of the present invention. With reference to FIG. 1, the apparatus 100 may be a semiconductor device such as a photogate that includes a semiconductor mesa 102 (e.g., fin). The semiconductor mesa 102 may have a width w between about 10 nm to about 1000 nm, and a depth d of about 100 nm to about 5000 nm. An oxide layer 104 may be coupled to the semiconductor mesa 102 and serve to isolate the mesa 102 from adjacent mesas, thereby serving as an inter-mesa isolation oxide. Further, gate conductor (e.g., a photo-gate conductor) material 106 may be formed along a plurality of sidewalls of the semiconductor mesa. For example, gate conductor material 106 may be formed along a first through third sidewalls 108, 110, 112 of the semiconductor mesa 102 and serve as respective gates for the semiconductor mesa 102. The third sidewall (112 in FIG. 4) and gate conductor material 106 coupled thereto are not shown in FIG. 1. A fourth sidewall 114 of the semiconductor mesa 102 may be coupled to a diffusion region 116. A top surface 117 of the semiconductor mesa 102 may be exposed.

During operation, when appropriate voltages are applied to the gates of the semiconductor mesa 102, depletion regions may form and merge within the semiconductor mesa 102. For example, a first depletion region 118 may form in the semiconductor mesa 102 and a second depletion region 120 may be formed in the semiconductor mesa 102. The second depletion region 120 may merge with the first depletion region 118 such that a large volume (e.g., substantially all of the semiconductor mesa 102 volume) may be depleted. Thus, gate-induced depletion regions may expand from sidewalls 108, 110, 112 of the semiconductor mesa 102 and merge within the semiconductor mesa 102. A depth of the depletion region may be based on (e.g., the same as) the depth d or height of the semiconductor mesa 102. For example, an entire volume of the semiconductor mesa 102 may be depleted such that an effective depth of the depletion region may be the height of the semiconductor mesa 102. For a substrate doping concentration of 1×10¹⁶ cm⁻³ or less, a semiconductor mesa width w of at least about 500 nm may be nearly fully depleted using standard present-day operating voltages (e.g., V_{dd}=1.0 V). Thus, instead of forming a photogate on a planar semiconductor surface with a depletion region expanding downward from the surface, the present invention may provide a semiconductor mesa structure with depletion regions 118, 120 controlled by gates on sidewalls 108, 110, 112 of the mesa 102. A system may include a plurality of the apparatus 100 arranged such that adjacent semiconductor mesas 102 may be spaced apart with a minimum definable lithographic spacing, thereby assuring a large fraction of the system contains depleted semiconductor.

The apparatus 100 may be adapted to create a signal in response to radiation hν, where h is Boltzmann's constant and ν is a frequency of the radiation, impacting the semiconductor device. When the radiation hν impacts the semiconductor mesa 102, a plurality of electron/hole pairs may be generated in the semiconductor mesa 102. In this manner, normally incident electromagnetic radiation impacting an exposed top surface 117 of the mesa 102 may create electron/hole pairs as the radiation penetrates through the depletion regions 118, 120. The depletion regions 118, 120 formed in the semiconductor mesa 102 may cause the electron and hole in each of the plurality of pairs to drift apart such that the signal is created in the semiconductor device. The signal may represent a change in voltage across the apparatus 100 caused by the radiation hν impact. A level (e.g., voltage) of the signal may be related to an intensity of the radiation. Because the depth of the depletion regions 118, 120 is based on the depth d of the semiconductor mesa 102, the volume of depletion regions 118, 120 of the apparatus 100 may be greater than depletion regions 118, 120 of conventional photodiodes and/or photogates. Further, because the top surface 117 of the semiconductor mesa 102 is exposed (e.g., not covered by a radiation absorbing layer such as gate conductor material), radiation impacting the apparatus 100 will not be attenuated before reaching the depletion regions 118, 120 as in some conventional photodiodes and/or photogates. Consequently, radiation incident the active depletion region 118, 120 may be more intense than similar radiation is on a conventional photodiode and/or photogate. Also, because the photogate includes a PN-junction that occupies a relatively small area, the photogate may result in fewer junction-related crystal defects, reduced thermal background generation, lower noise floor and larger dynamic range.

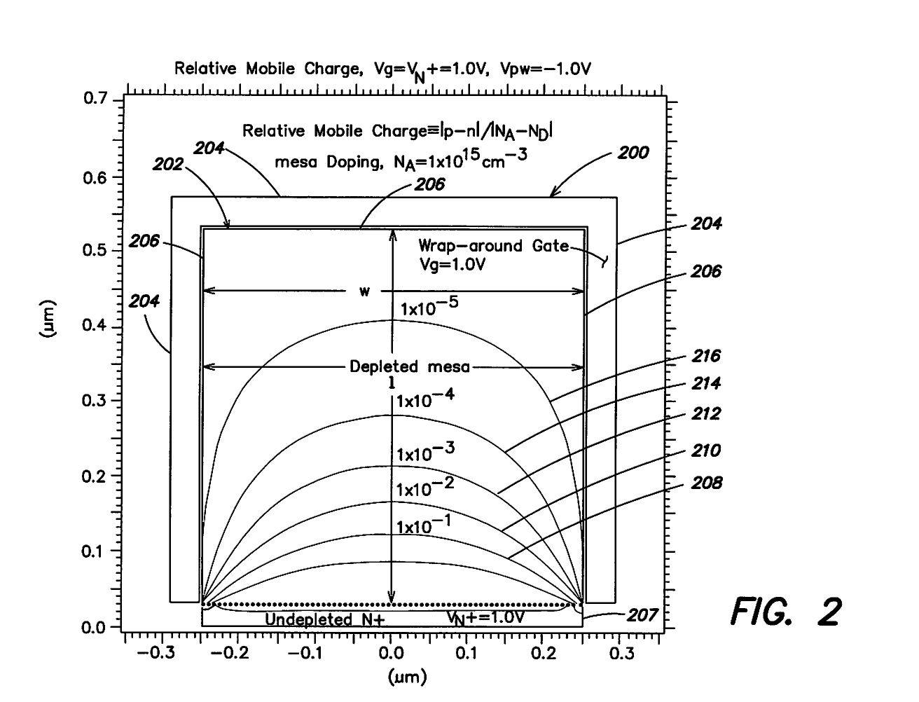

FIG. 2 illustrates a horizontal cross-sectional view of a simulated version of a first exemplary apparatus 200 for determining radiation intensity in accordance with an embodiment of the present invention. With reference to FIG. 2, the first exemplary apparatus 200, which may be a photogate, includes a semiconductor mesa 202 with a gate 204 coupled to (e.g., wrapped around) three sidewalls 206 thereof. A diffusion region (e.g., N+ doped) 207 may be coupled to a remaining 206 sidewall of the semiconductor mesa 202. A width w and length (e.g., length l) of the semiconductor mesa 202 are both 500 nm. The semiconductor mesa 202 includes P-type dopant with a concentration of 1×10¹⁵ cm⁻³. During simulated operation of the first exemplary apparatus 200, a voltage Vg of 1.0 V, voltage V_{N+} of 1.0 V and voltage Vpw of −1.0 V may be applied to the gate 204, an N+ diffusion region and a P-well region of the photogate, respectively. Contours 208-216 of relative mobile charge (|P−N|/|N_{A}−N_{D}|) that form in the semiconductor mesa 202 during such operation are shown, where P is a hole concentration, N is an electron concentration, N_{A} is a p-type dopant and N_{D} is an n-type dopant. Values of relative mobile charge (as illustrated by the contours 208-216) of less than 1×10⁻² correspond to regions which are at least 99% depleted of mobile charge carriers. In contrast, a relative mobile charge value of 1 may correspond to a completely undepleted region. As shown, even when a semiconductor mesa 202 as wide as 500 nm is employed, greater than 99% depletion may occur throughout a major gated portion of the semiconductor mesa 202. Thus, full or nearly full depletion exists within most of the gated portion of the semiconductor mesa 202.

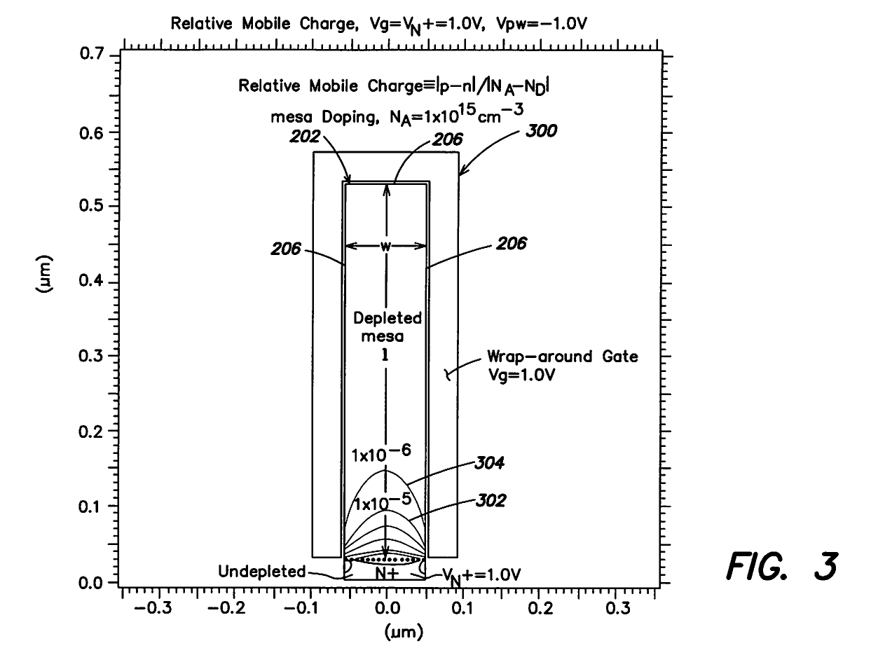

FIG. 3 illustrates a horizontal cross-sectional view of a simulated version of a second exemplary apparatus 300 for determining radiation intensity in accordance with an embodiment of the present invention. With reference to FIG. 3, the structure and operational voltages employed during simulation for the second exemplary apparatus 300 are similar to the first exemplary apparatus 200. However, the semiconductor mesa width w is reduced to 100 nm. Consequently, the gates along the mesa sidewalls 206 (e.g., side-gates) may influence increased control of the silicon potential, and therefore, a much greater fraction of the volume of the semiconductor mesa 202 is depleted. To with, due to stronger gate control, a much larger volume of the 100 nm-wide semiconductor mesa 202 of the second exemplary apparatus 300 is depleted than for the 500 nm-wide semiconductor mesa 202 of the first exemplary apparatus 200. Contours 302-304 of relative mobile charge that form in the semiconductor mesa 202 of the second exemplary apparatus 300 during operation are shown.

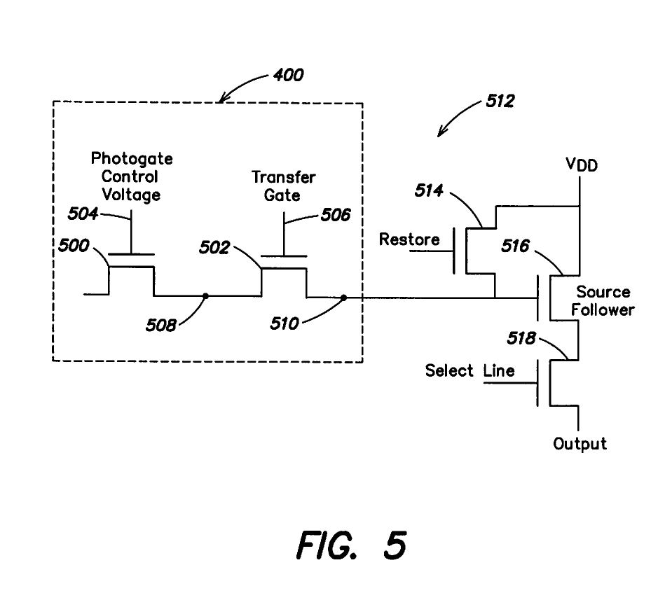

FIG. 4 is a top view of a first exemplary system 400 for determining radiation intensity in accordance with an embodiment of the present invention. With reference to FIG. 4, the system 400 may include a plurality of the apparatus 100 for determining radiation intensity formed on a substrate 401. For example, the layout of the system 400 may include four apparatus 100, each of which includes a semiconductor mesa 102 having a gate conductor material layer 106 formed on sidewalls (e.g., three sidewalls) thereof. The gate conductor material layer 106 may serve as gates of the apparatus 100. The gate conductor material layer 106 may be unsilicided. By combining a plurality of such apparatus 100, the sensitivity of the system 400 may be increased. For example, the top view of the system layout illustrates four side-gated semiconductor mesas 102 combined in parallel. A diffusion region 116 of each apparatus 100 may be coupled to respective transfer gates 402 (although a single transfer gate may be employed to couple the plurality of apparatus 100). The transfer gate 402 may be silicided. Further, the system 100 may include collection diffusion region 404 coupled to the plurality of apparatus 100 via respective diffusion regions 116 thereof. Signals created in the plurality of apparatus 100 based on or related to radiation impact may be transmitted to the collection diffusion region 404 via the respective transfer gates 402. The collection diffusion region 404 may be coupled, via contacts 405, to additional circuitry adapted to determine an intensity of the radiation based on the signals in the collection diffusion region 404 having a level related to the intensity. Such additional circuitry is described below with reference to FIG. 5. The system 400 may be coupled to shallow trench isolation (STI) regions 406, which may isolate the system 400 from other devices formed on the substrate 401. The STI/system boundary is shown by dotted line 408.

The spacing between semiconductor mesas 102 may be the allowable minimum lithographic mesa-to-mesa spacing. Further,

during operation, semiconductor mesas 102 of each of the plurality of apparatus 100 may become fully or nearly fully depleted. Therefore, the active photogate area density of the system may be superior to that of conventional systems. For example, for a system layout including semiconductor mesas 102 having 500 nm widths, respectively, and 45 nm mesa-to-mesa spacing (e.g., employing 45 nm technology node), a volume efficiency of the photogate (e.g., sensor) may be greater than about 95% (excluding the small volume occupied by the diffusion region 116). More specifically, more than 95% of the volume of the photogate structure (excluding PD diffusion) may contribute to the creation or collection of photo-generated carriers, thereby increasing photo-efficiency of the system 400.

FIG. 5 is a schematic circuit representation of the system of FIG. 4 in accordance with an embodiment of the present invention. With reference to FIG. 5, the system 400 may be represented as a first transistor 500 coupled to a second transistor 502. The gate conductor material layer 106 may serve as gate 504 of the first transistor 500 to which a control voltage (e.g., photogate control voltage) may be applied. The transfer gate 402 may serve as a gate 506 of the second transistor 502. The diffusion region 116 may serve as a node 508 between the first and second transistors 504, 506. Additionally, the collection diffusion region 404 may serve as another node 510 of the system 400. Additionally circuitry 512 adapted to determine an intensity of the radiation based on the signals (having a level related to the intensity) in the collection diffusion region 404 may be coupled to the node 510. The additional circuitry 512 may include a restore, source follower and select transistors 514, 516, 518. Such additional circuitry 512 is known to one of skill in the art, and therefore, is not described in detail herein.

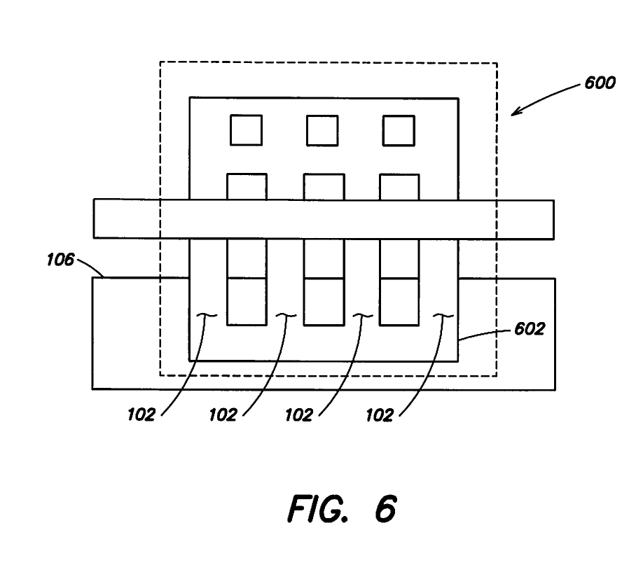

FIG. 6 is a top view of a second exemplary system 600 for determining radiation intensity in accordance with an embodiment of the present invention. With reference to FIG. 6, the second exemplary system 600 is similar to the first exemplary system 400. However, the semiconductor mesas 102 in the second exemplary system 600 are coupled together (e.g., via another mesa 602). For example, ends of the semiconductor mesas 102 may be tied together to further increase an active volume of the photogate 400. More specifically, during operation, a depletion region may form in such a mesa 602. Consequently, the second exemplary system 600 may provide a larger volume of fully depleted or nearly fully depleted silicon than the first exemplary system 400. However, forming the gate conductor material 106 along sidewalls of semiconductor mesas 102 of the second exemplary system 600 is more difficult than in the first exemplary system 400.

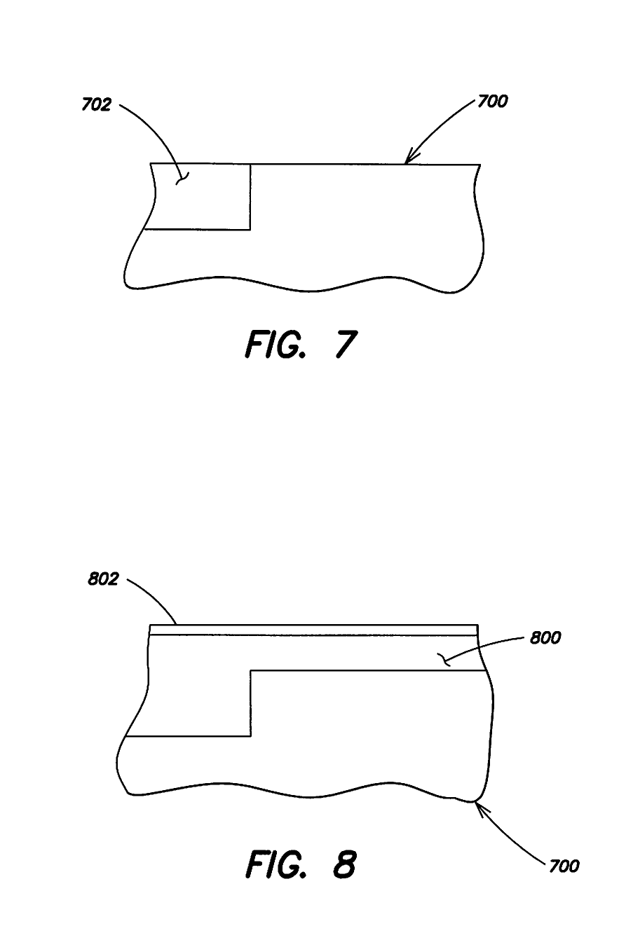

A method of manufacturing the apparatus 100 and system 400 including such apparatus 100 for determining radiation intensity is described below with reference to FIGS. 7-15D. FIG. 7 illustrates a cross-sectional side view of a substrate 700 following a first step of a method of manufacturing an apparatus for determining radiation intensity in accordance with an embodiment of the present invention. In FIG. 7, the cross-sectional side view is taken along cut lines 7-7. With reference to FIG. 7, the substrate 700 may be a silicon substrate. Standard processing may be employed to define shallow trench isolation (STI) regions 702 on the substrate 700. For example, one or more pad films may be deposited, patterned and etched on the substrate 700. Reactive ion etching (RIE) or another suitable method may be employed to form one or more shallow trenches in the substrate 700. Thereafter, chemical vapor deposition (CVD) or another suitable method may be employed to fill such trenches with oxide. Etching or another suitable method may be employed remove (e.g., strip) the pad films from the substrate 700. The STI regions 702 may serve to isolate the system 400 being manufactured from other devices formed on the substrate 700.

FIG. 8 illustrates a cross-sectional side view of the substrate 700 following a second step of the method of manufacturing an apparatus for determining radiation intensity in accordance with an embodiment of the present invention. In FIG. 8, the cross-sectional side view is taken along cut lines 8-8. With reference to FIG. 8, CVD or another suitable method may be employed to form a first layer of oxide 800 on the substrate 700. Chemical mechanical planarization (CMP) or another suitable method may be employed to planarize the surface of the substrate 700. Such an oxide layer 800 may serve to isolate adjacent mesas which may subsequently be formed on the substrate 700, thereby serving as an inter-fin isolation oxide which may reduce capacitance between one or more subsequently-formed gates and substrate 700. The oxide layer 800 may be about 20 nm to about 100 nm thick. CVD or another suitable method may be employed to form a first layer 802 of nitride on the substrate 700. The nitride layer 802 may be about 5 nm to about 20 nm thick, and may subsequently serve as an oxide etch stop. A larger or smaller and/or different thickness range may be employed for the oxide layer 800 and/or nitride layer 802.

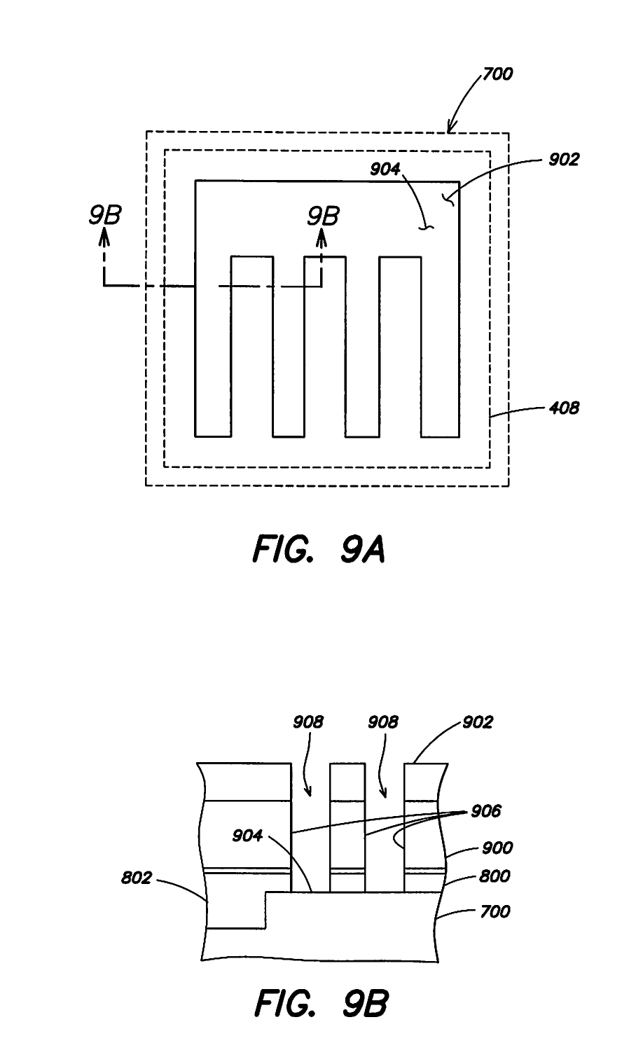

FIGS. 9A-B illustrate respective top and cross-sectional side views of the substrate following a third step of the method of manufacturing an apparatus for determining radiation intensity in accordance with an embodiment of the present invention. In FIG. 9B, the cross-sectional side view is taken along cut lines 9B-9B. With reference to FIGS. 9A-B, CVD or another suitable method may be employed to form a second layer 900 of oxide on the substrate 700. The second oxide layer 900 may be about 200 nm to about 5000 nm thick. Similarly, CVD or another suitable method may be employed to form a second layer of nitride 902 which may subsequently serve as a nitride polish stop. The second nitride layer 902 may be about 50 nm to about 200 nm thick. However, a larger or smaller and/or different thickness range may be employed for the second oxide layer 900 and/or second nitride layer 902. The combined thickness (e.g., height) of the second oxide layer 900 and second nitride layer 902 may determine a height or depth of one or more subsequently-formed semiconductor mesas.

A layer of photoresist may be applied to the substrate 700 and patterned. More specifically, the photoresist layer may be applied, exposed and developed. In this manner, the patterned photoresist layer may define a region in which a semiconductor mesa will be formed. More specifically, the patterned photoresist layer and RIE or another suitable method may be employed to form cavities though the dielectric layers 800, 802, 900, 902 down to a surface 904 of the substrate 700. By employing RIE, sidewalls 906 of the substantially-vertical etched cavities 908 may be vertical.

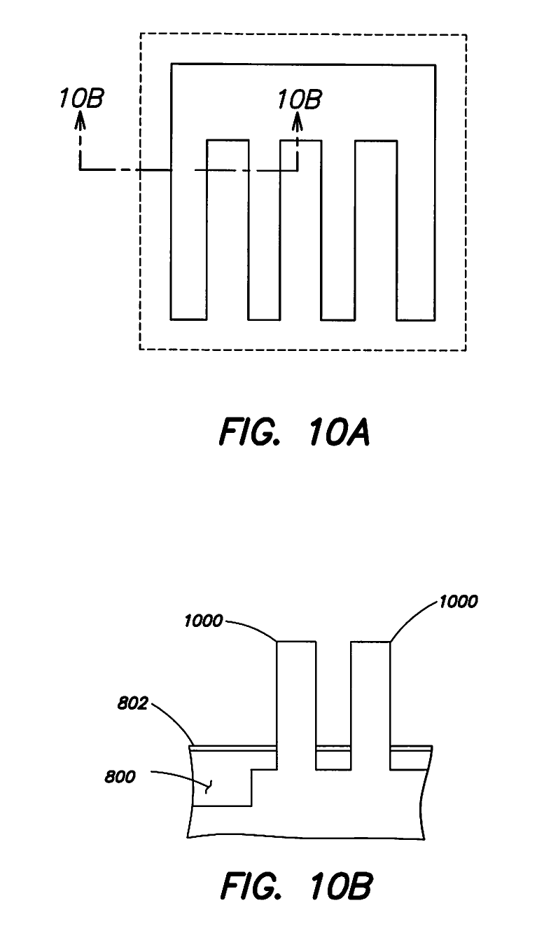

FIGS. 10A-B illustrate respective top and cross-sectional side views of the substrate following a fourth step of the method of manufacturing an apparatus for determining radiation intensity in accordance with an embodiment of the present invention. In FIG. 10B, the cross-sectional side view is taken along cut lines 10B-10B. With reference to FIGS. 10A-B, selective epitaxy or another suitable method may be employed to grow or extend the exposed semiconductor surface (904 in FIG. 9B) through the cavity (908 in FIG. 9B). Selective epitaxy may be employed to grow semiconductor material (e.g., silicon) 1000 slightly above a top surface of the nitride polish stop layer (902 in FIG. 9B). CMP or another suitable method may be employed to planarize the silicon, which may serve as a semiconductor mesa (1000 in FIG. 10B). Thereafter, a hot phosphoric acid etch, hydrofluoric acid (HF) with ethylene glycol etch or another suitable method may be employed to remove or strip the second layer of nitride (902 in FIG. 9B) selective to the semiconductor (e.g., silicon) (902 in FIG. 9B) and second oxide layer (900 in FIG. 9B). Isotropic etching, which typically may include HF, may be employed to remove the second oxide layer 900 selective to nitride. In this manner, the first nitride layer 802 may protect the inter-fin oxide 800 during the etching. In this manner, one or more semiconductor mesas 1000 of the system 400 being manufactured may be formed.

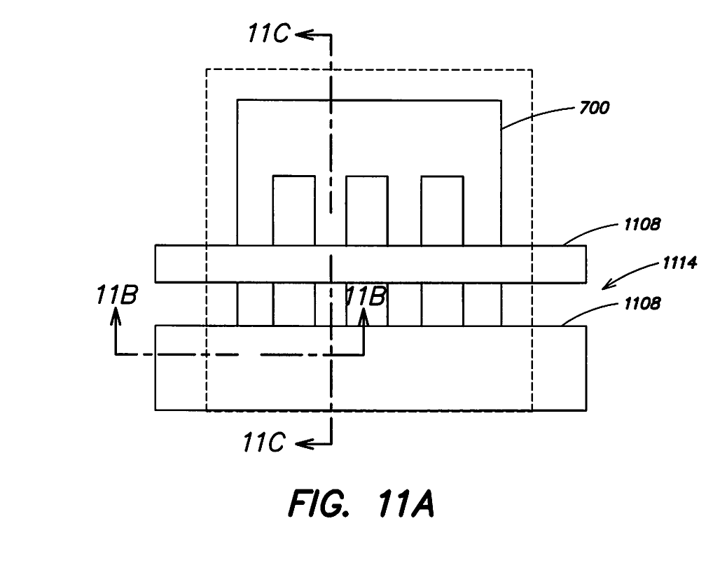

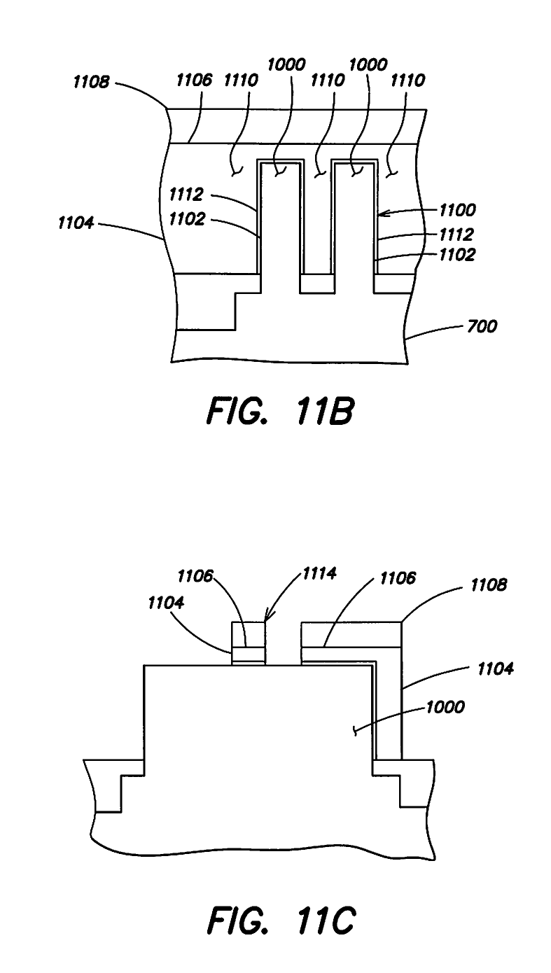

FIGS. 11A-C illustrate respective top, cross-sectional side and cross-sectional front views of the substrate following a fifth step of the method of manufacturing an apparatus for determining radiation intensity in accordance with an embodiment of the present invention. In FIGS. 1B-11C, the cross-sectional side and front views are taken along cut lines 11B-11B and 11C-11C, respectively. With reference to FIGS. 11A-C, RIE or another suitable method may be employed to remove or strip the first nitride layer 802 from the substrate 700. However, in some embodiments, the first nitride layer 802 may not be removed. Chemical reaction (e.g. thermal oxidation or nitridation), CVD or another suitable method may be employed to form a gate dielectric material layer 1100 on surfaces (e.g., along sidewalls 1102) of the semiconductor mesas 1000. The gate dielectric material may include silicon oxide, silicon nitride, silicon oxynitride, aluminum oxide and/or one or more high-K dielectrics. However, the gate dielectric material may include one or more additional and/or different materials.

CVD or another suitable method may be employed to deposit a gate conductor (e.g., photo-gate conductor) 1104, such as polysilicon or another suitable material, on the substrate 700 such that the gate conductor material 1104 may fill the gaps between and/or adjacent the semiconductor mesas 1000. CMP or another suitable method may be employed to planarize the gate conductor material 1104 to a level above a top surface of the semiconductor mesa 1000. Portions of the gate conductor material 1104 may serve as a gate of an apparatus 100 included in the system 400 and portions of the gate conductor material 1104 may serve as a transfer gate of the system 400. In some embodiments, the gate conductor material 1104 may be doped in situ during deposition to establish a work function of a photogate and/or a transfer gate formed by the gate conductor material 1104. However, the gate conductor material 1104 may be doped differently (e.g., using a separate implant or diffusion process).

One or more block masks may be employed while removing gate conductor material from other regions of the substrate 700 (e.g., a chip thereon) and/or while performing gate conductor material deposition steps for other devices (not shown) on the substrate 700. Employing block masks in this manner is known to one of skill in the art.

A top surface 1106 of the planarized gate conductor material layer 1104 may then be silicided to form a silicide layer 1108. During silicidation, deposition of a reactive metal, such as tungsten, titanium, tantalum, cobalt, nickel and/or the like, may be followed by annealing which causes the metal to react with the semiconductor (e.g., silicon) to form a highly-conductive silicide layer 1108. Because silicidation is known to one of skill in the art, it is not described in further detail herein. The gate conductor material (e.g., polysilicon) layer 1104 and the silicide layer 1108 may collectively be referred to as the gate stack. Photolithography using photoresist and appropriate masking, followed by RIE or another suitable method may be employed to pattern the gate stack such that gates 1110 may be formed along sidewalls 1112 of the mesas 1000, and such that a transfer gate 1114 of the system 400 may be formed.

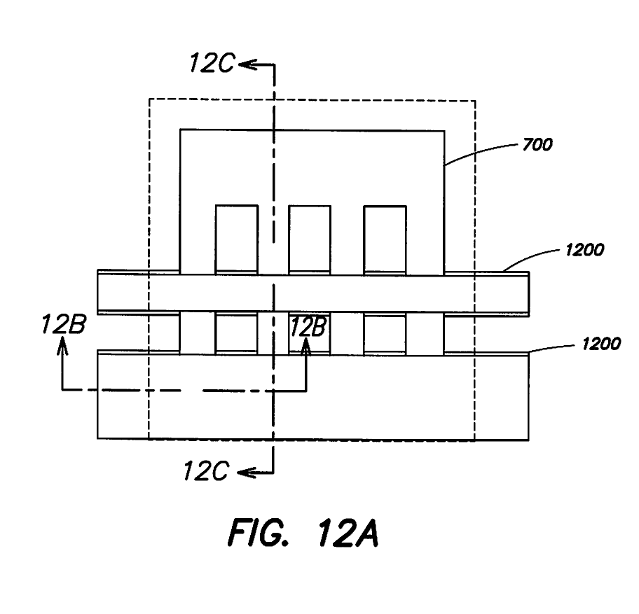

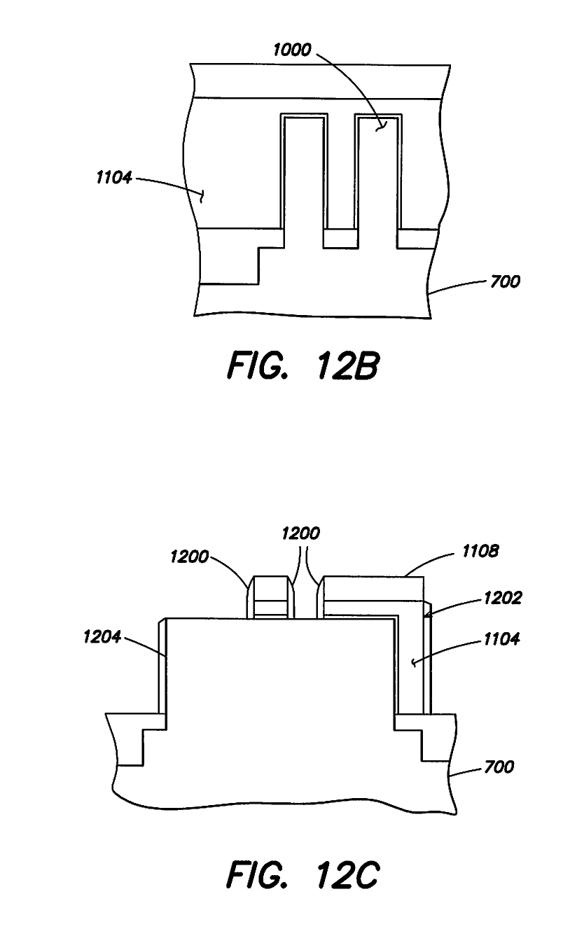

FIGS. 12A-C illustrate respective top, cross-sectional side and cross-sectional front views of the substrate 700 following a sixth step of the method of manufacturing an apparatus for determining radiation intensity in accordance with an embodiment of the present invention. In FIGS. 12B-12C, the cross-sectional side and front views are taken along cut lines 12B-12B and 12C-12C, respectively. With reference to FIGS. 12A-C,

CVD or another suitable method may be employed to form a conformal nitride layer on the substrate 700. Thereafter, RIE or another suitable method may be employed to remove portions of the nitride layer such that nitride spacers 1200 may be formed along the vertically oriented surfaces of gate stack 1202 (e.g., along gates of apparatus 100 included in the system 400), and vertically oriented surfaces of semiconductor material substrate 700. Sidewalls 1204 of portions of the semiconductor material may be exposed.

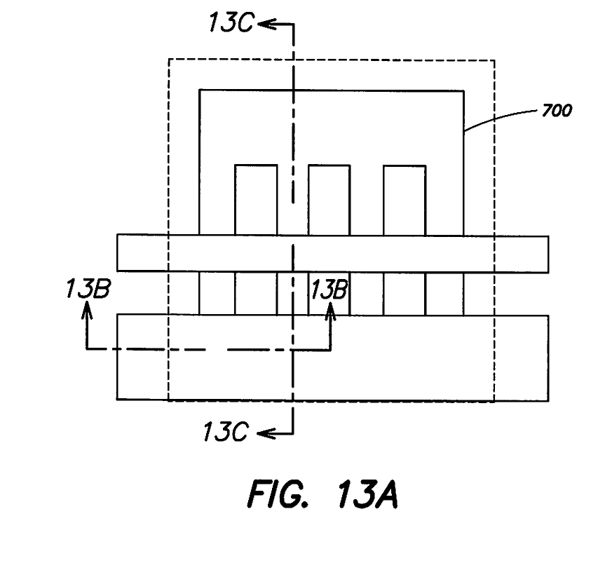

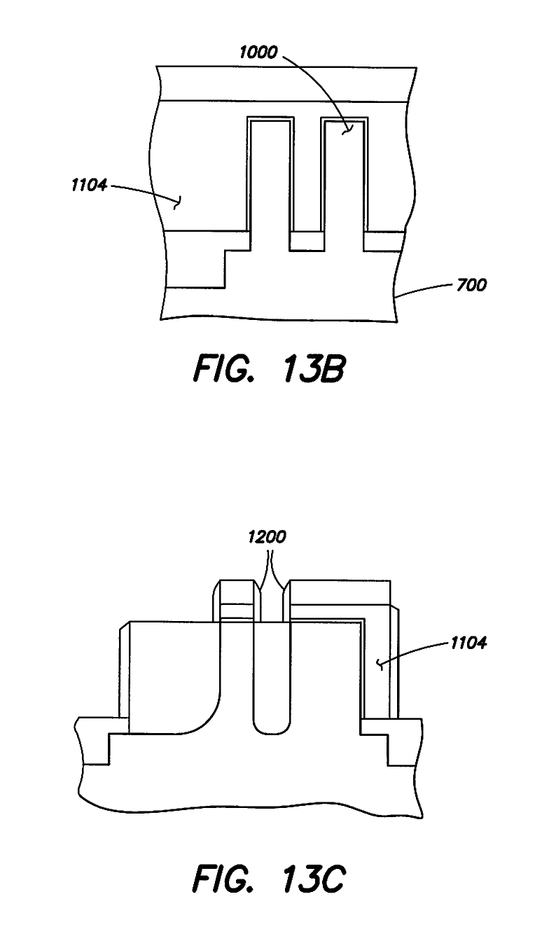

FIGS. 13A-C illustrate respective top, cross-sectional side and cross-sectional front views of the substrate 700 following a seventh step of the method of manufacturing an apparatus for determining radiation intensity in accordance with an embodiment of the present invention. In FIGS. 13B-13C, the cross-sectional side views are taken along cut lines 13B-13B and 13C-13C, respectively. With reference to FIGS. 13A-C, source/drain diffusion implantation may be employed to form diffusion regions, such as a collection diffusion region and a photo diode (PD) diffusion region on the substrate 700. Extension implantation may also be performed. The gate conductor material layer 1104 may serve as a mask during such implantation. Because sidewalls (1204 in FIG. 12) of portions of the semiconductor material are exposed, the implantation may be angled such that dopant may be implanted deep in such portions. Halos may be implanted into such portions. The halo implantation may improve Vt control for apparatus 100 included in the system 400 being manufactured. To facilitate expansion of depletion regions in the semiconductor mesas 1000 of apparatus 100 included in the system being manufactured, it is desired that the photosensitive portions of the mesas 1000 should remain lightly doped. Consequently, one or more block masks may be employed to protect such regions during halo implantation to form other devices.

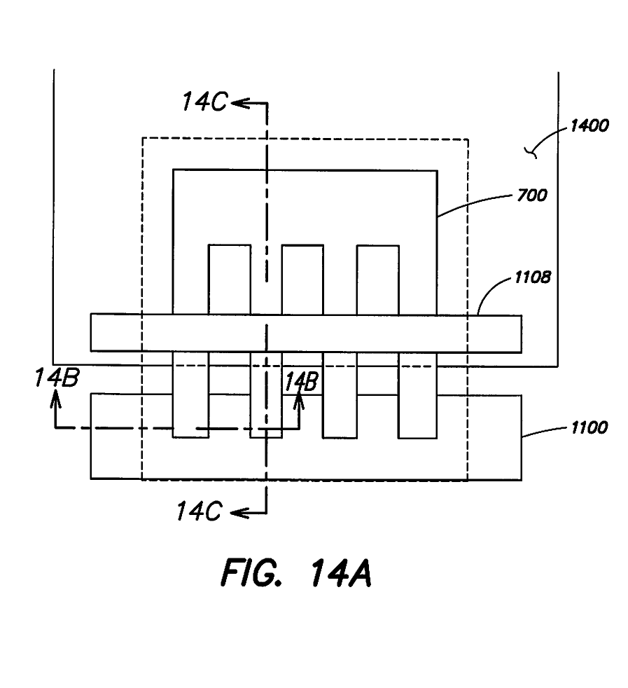

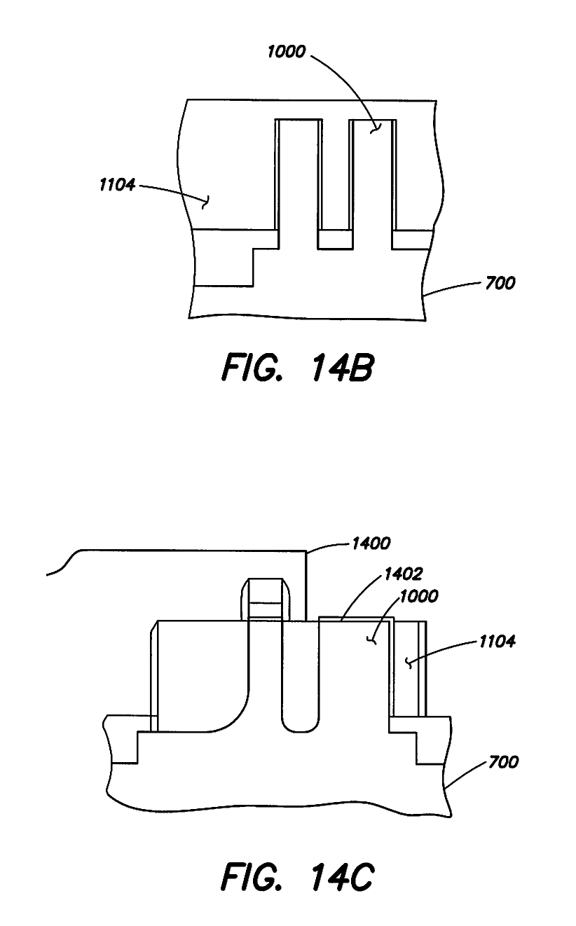

FIGS. 14A-C illustrate respective top, cross-sectional side and cross-sectional front views of the substrate 700 following an eighth step of the method of manufacturing an apparatus for determining radiation intensity in accordance with an embodiment of the present invention. In FIGS. 14B-14C, the cross-sectional side views are taken along cut lines 14B-14B and 14C-14C, respectively. With reference to FIGS. 14A-C, photolithography using the resist and appropriate masking may be employed to form a block mask 1400. However, another suitable mask (e.g., a hard mask) may be formed. The block mask 1400 may be employed to expose portions of the gate conductor material which serve as the gate 1100 and protect remaining portions of the substrate 700. The block mask 1400 along with RIE or another suitable method may be employed to remove exposed portions of the silicide layer (1108 in FIG. 11) until a top surface 1402 of the semiconductor mesa 1000 is exposed. Further, RIE or another suitable method may be employed to remove (e.g., recess) exposed portions of the gate conductor layer 1104 such that the gate conductor layer 1104 may be coplanar with the top surface 1402 of the semiconductor mesa 1000. Optionally, gate dielectric 1100 may be allowed to remain on top surface 1402.

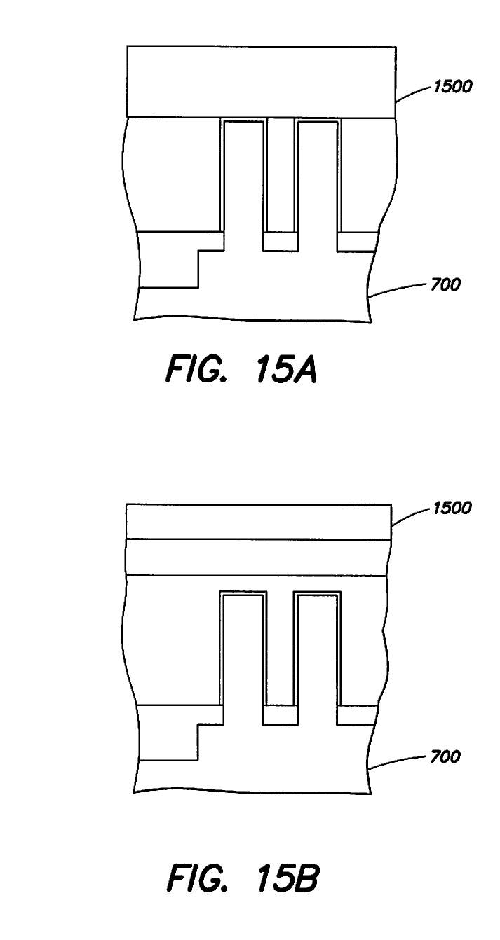

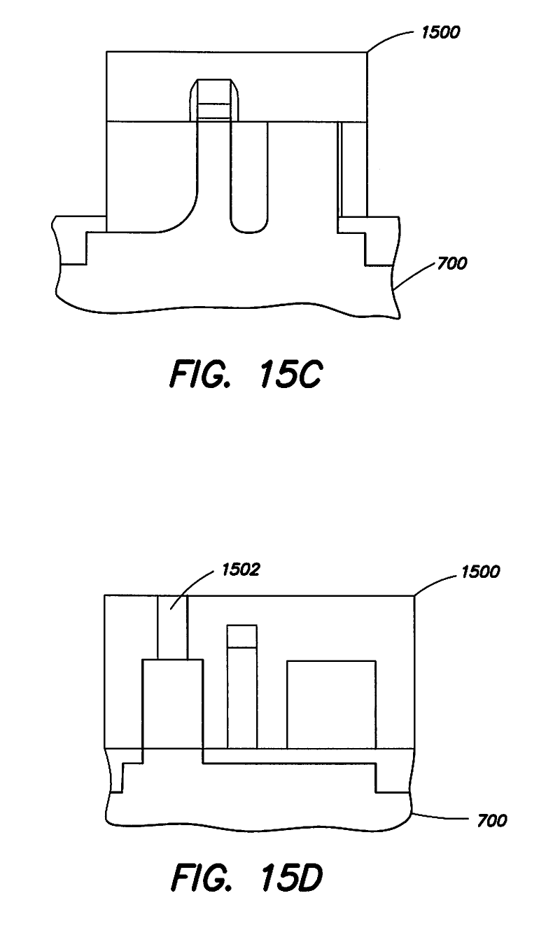

FIGS. 15A-D illustrate first cross-sectional side, second cross-sectional side, first cross-sectional front and second cross-sectional front views of the substrate following a ninth step of the method of manufacturing an apparatus for determining radiation intensity in accordance with an embodiment of the present invention. In FIGS. 15B-15D, the cross-sectional side views are taken along cut lines 15A-15A, 15B-15B, 15C-15C and 15D-15D, respectively, as defined in FIG. 4. With reference to FIGS. 15A-D, CVD or another suitable technique may be employed to deposit a primary layer dielectric 1500 (e.g., using a Tetraethylorthosilicate (TEOS) precursor) onto the substrate 700. At this point is the process, a primary layer dielectric (preferably TEOS) 1500 is deposited and planarized over the structure 700. RIE or another suitable method may be employed to form contact vias in the TEOS layer 1500. Thereafter, contact metallurgy 1502 (e.g., a diffusion contact) may be formed using methods known to one of skill in the art. In this manner, the system 400 for determining radiation intensity may be formed. It should be noted, in FIG. 4, the TEOS layer 1500 is omitted for clarity. Standard processing continues through completion of the chip. For example, standard processing may be employed to form additional interlevel dielectric layers, conductive vias, wiring levels, etc.

Through use of the present methods of manufacturing, an efficient optical sensor 100 (e.g., photogate optical sensor) may be created. Such optical sensor 100 may be employed for image sensing, optical interconnect applications and/or another suitable application. During operation, an electric field may be formed in the semiconductor mesa 102. Such field may be caused by a gate bias voltage. In this manner, a PN-junction of the photogate 100 may be pre-charged to a reverse bias and left floating. When radiation impacts the apparatus 100, electron/hole pairs may be created in the depletion regions 118, 120. Under the influence of an electric field in the depletion region, the generated electron and hole of each pair may drift in opposite directions and may be collected by a cathode and anode of a reverse-biased junction, respectively, of the photogate 100. If the PN-junction is pre-charged to a reverse bias and left floating, collection of the generated carriers under illumination may cause the PN-junction to discharge. The decrease in reverse bias of the PN-junction is related to the time integral of the amplitude of the illumination. The decrease in reverse bias on the PN-junction may be sensed and may represent the output from a particular picture element (e.g., photogate). Additionally circuitry may be employed to determine the intensity of the radiation based on the decrease in reverse bias of the PN-junction, which has a level related to the intensity. The dimensions (e.g., depth d or height) of the semiconductor mesa 102 may enable depletion regions 118, 120 with a large volume to be formed. Therefore, a large change in the reverse-bias of the PN-junction may be formed in response to radiation impacting the optical sensor 100. Consequently, the optical sensor 100 including a semiconductor mesa 102 may be highly-sensitive.

The foregoing description discloses only exemplary embodiments of the invention. Modifications of the above disclosed apparatus and methods which fall within the scope of the invention will be readily apparent to those of ordinary skill in the art. For instance, the substrate 700 may be a bulk substrate or a silicon-on-insulator (SOI) substrate.

Accordingly, while the present invention has been disclosed in connection with exemplary embodiments thereof, it should be understood that other embodiments may fall within the spirit and scope of the invention, as defined by the following claims.

The invention claimed is:

1. A method of determining radiation intensity, comprising:
providing a semiconductor device having:
a silicon mesa; and
photo-gate conductor material along at least three sidewalls of the silicon mesa;
forming a depletion region in the silicon mesa; and
in response to radiation impacting the semiconductor device, creating a signal in the semiconductor device that has a level related to an intensity of the radiation.

2. The method of claim 1 wherein forming the depletion region in the silicon mesa includes forming the depletion region in substantially an entire volume of the silicon mesa.

3. The method of claim 2 wherein forming the depletion region in the silicon mesa includes:
employing photo-gate conductor material along a first sidewall of the silicon mesa such that a first gate-induced depletion region forms in a portion of the silicon mesa adjacent the first sidewall; and
employing photo-gate conductor material along a second sidewall of the silicon mesa such that a second gate-induced depletion region forms in a portion of the silicon mesa adjacent the second sidewall and merges with the first gate-induced depletion region.

4. The method of claim 2 wherein forming the depletion region in the silicon mesa includes forming the depletion region in substantially an entire depth of the silicon mesa.

5. The method of claim 1 wherein the semiconductor device further includes:
a transfer gate; and
a collection diffusion; and
further comprising transmitting the signal from the silicon mesa to the collection diffusion via the transfer gate.

6. The method of claim 1 wherein creating the signal in the semiconductor device in response to radiation impacting the semiconductor device includes:
generating a plurality of electron/hole pairs in the silicon mesa; and
causing the electron and hole in each of the plurality of pairs to drift apart such that the signal is created in the semiconductor device.

7. An apparatus for determining radiation intensity, comprising:
a semiconductor device having:
a silicon mesa; and
photo-gate conductor material along at least three sidewalls of the silicon mesa;
wherein the semiconductor device is adapted to:
form a depletion region in the silicon mesa; and
create a signal in the semiconductor device in response to radiation impacting the semiconductor device, wherein the signal has a level related to an intensity of the radiation.

8. The apparatus of claim 7 wherein the semiconductor device is further adapted to form the depletion region in substantially an entire volume of the silicon mesa.

9. The apparatus of claim 8 wherein the semiconductor device is further adapted to:
employ photo-gate conductor material along a first sidewall of the silicon mesa such that a first gate-induced depletion region forms in a portion of the silicon mesa adjacent the first sidewall; and
employ photo-gate conductor material along a second sidewall of the silicon mesa such that a second gate-induced depletion region forms in a portion of the silicon mesa adjacent the second sidewall and merges with the first gate-induced depletion region.

10. The apparatus of claim 8 wherein the semiconductor device is further adapted to form the depletion region in substantially an entire depth of the silicon mesa.

11. The apparatus of claim 7 wherein:
the semiconductor device further includes:
a transfer gate; and
a collection diffusion; and
the semiconductor device is further adapted to transmit the signal from the silicon mesa to the collection diffusion via the transfer gate.

12. The apparatus of claim 7 wherein the semiconductor device is further adapted to:
generate a plurality of electron/hole pairs in the silicon mesa; and
cause the electron and hole in each of the plurality of pairs to drift apart such that the signal is created in the semiconductor device.

13. The apparatus of claim 7 wherein a top surface of the silicon mesa is exposed.

14. The apparatus of claim 7 wherein a depth of the silicon mesa is about 1000 nm.

15. The apparatus of claim 7 wherein a concentration of p-type dopant in the silicon mesa is about 1×10¹⁵ cm⁻³.

16. A system for determining radiation intensity, comprising:
a substrate; and
at least one semiconductor device formed on the substrate,
the semiconductor device having:
a silicon mesa; and
photo-gate conductor material along at least three sidewalls of the silicon mesa;
wherein the semiconductor device is adapted to:
form a depletion region in the silicon mesa; and
create a signal in the semiconductor device in response to radiation impacting the semiconductor device, wherein the signal has a level related to an intensity of the radiation.

17. The system of claim 16 wherein the semiconductor device is further adapted to form the depletion region in substantially an entire volume of the silicon mesa.

18. The system of claim 17 wherein the semiconductor device is further adapted to:
employ photo-gate conductor material along a first sidewall of the silicon mesa such that a first gate-induced depletion region forms in a portion of the silicon mesa adjacent the first sidewall; and
employ photo-gate conductor material along a second sidewall of the silicon mesa such that a second gate-induced depletion region forms in a portion of the silicon mesa adjacent the second sidewall and merges with first gate-induced depletion region.

19. The system of claim 17 wherein the semiconductor device is further adapted to form the depletion region in substantially an entire depth of the silicon mesa.

20. The system of claim 16 wherein:
the semiconductor device further includes:
a transfer gate; and
a collection diffusion; and
the semiconductor device is further adapted to transmit the signal from the silicon mesa to the collection diffusion via the transfer gate.

21. The system of claim 16 wherein the semiconductor device is further adapted to:
generate a plurality of electron/hole pairs in the silicon mesa; and
cause the electron and hole in each of the plurality of pairs to drift apart such that the signal is created in the semiconductor device.

22. The system of claim 16 wherein a top surface of the silicon mesa is exposed.

23. The system of claim 16 wherein a depth of the silicon mesa is about 1000 nm.

24. The system of claim 16 wherein a concentration of p-type dopant in the silicon mesa is about 1×10¹⁵ cm⁻³.

25. The system of claim 16 wherein the substrate is a bulk substrate or a silicon-on-insulator substrate.
